(19) United States
(12) Patent Application Publication
(10) Pub. No.: US 2009/0032143 A1
(43) Pub. Date: Feb. 5, 2009

(54) ELECTRON BEAM ENHANCED NITRIDING SYSTEM

(76) Inventors: Scott G Walton, Burke, VA (US); Darrin Leonhardt, Gaithersburg, MD (US); Robert A. Meger, Crofton, MD (US); Richard F. Fernsler, Annandale, VA (US); Christopher Muratore, Alexandria, VA (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 12/182,231

(22) Filed: Jul. 30, 2008

Related U.S. Application Data
(62) Division of application No. 10/874,002, filed on Jun. 22, 2004.

(51) Int. Cl. C23C 8/36; C23C 16/513; C23C 8/24

(52) U.S. Cl. 148/222; 118/723 FE

(57) ABSTRACT

An electron beam enhanced nitriding system that passes a high-energy electron beam through nitrogen gas to form a low electron temperature plasma capable of delivering nitrogen ions and radicals to a substrate to be nitrided. The substrate can be mounted on an electrode, and the substrate can be biased and heated.

### BACKGROUND

1. Field of the Invention

The present invention relates to nitriding systems and, more specifically, to a system for nitriding materials using plasmas produced by high-energy electron beams.

2. Description of the Related Art

Nitriding generally refers to a process designed to increase the concentration of nitrogen at the surface of a material. The depth to which the incorporated nitrogen extends varies but is typically 1 to 10 microns. Nitriding processes are currently employed to improve the hardness and wear resistance of materials with otherwise attractive engineering properties. Corrosion resistant stainless steel for example is a relatively soft material that can be nitrided to increase the surface hardness. Aluminum alloys possess high strength-to-weight ratios; however, these materials typically exhibit high wear rates in high friction or high force environments, which can be decreased by nitriding.

Nitriding is a treatment process for materials that results in increased hardness and wear resistance due to an alteration of the chemical composition and physical structure of the surface. The process involves subjecting a material, typically a metal, to a nitrogen-rich, chemically active atmosphere that promotes diffusion of nitrogen atoms into the bulk material. To facilitate nitrogen diffusion, the process is frequently performed at high temperatures with respect to the melting point (Tₘ) of the material (>0.5 Tₘ). However, many engineering materials exhibit undesirable property changes, such as loss of corrosion resistance or overtempering below the temperatures necessary to get useful nitrided layers in an acceptable period of time with respect to typical product manufacturing times (i.e., less than tens of hours). To accelerate diffusion at reduced temperatures, a plasma or glow discharge in the vicinity of the material can be employed. In the absence of plasma, chemical reactions are entirely dependent on thermal energy. A plasma or glow discharge however, contains chemically reactive species such as atomic radicals (N), atomic ions (N⁺), and excited molecular (N₂*) nitrogen species that are produced by electron-molecule collisions. These chemically active species supplement the thermally induced reactions at the surface, allowing for increased diffusion at lower temperatures. Additionally, nitrogen ions (N₂⁺ and N⁺) in the plasma can be accelerated toward the material by external biasing techniques, typically a dc or rf voltage applied to the material.

A common approach to plasma-based nitriding is to generate the plasma by applying a negative voltage to the material (or workpiece) to be nitrided, the magnitude of the voltage being sufficient to cause electrical breakdown of the ambient gas. However, there are difficulties associated with this technique. Temperature control at the material surface is difficult to achieve as the current necessary to sustain the discharge results in unpredictable resistive heating of the nitrided material. Furthermore, nitriding of large areas is often desirable, but may be limited by the output of the system power supplies because large currents are necessary to drive large areas to typical discharge voltages (500-1000 Volts). Additionally, the applied negative voltage, while necessary to sustain the glow discharge, will result in positive ion energies that may be different from the most effective ion energy for nitriding. The process gas pressure can be manipulated to alter the glow discharge; however, the gas pressure will have a significant impact on the neutral and ion flux.

During the last few years, the Charged Particle Physics Branch (Code 6750) at the Naval Research Laboratory (NRL) has developed a new plasma source called the Large Area Plasma Processing System (LAPPS). See U.S. Pat. No. 5,182,496 to Manheimer et al.; U.S. Pat. No. 5,874,807 to Neger et al.; Physics of Plasmas, 5(5), 2137-2143, 1998; Plasma Sources Sci. Technol., 9, 370-386, 2000; Journal of Vacuum Science and Technology A, 19(4), 1325-1329, 2001; Journal of Vacuum Science and Technology A, 19(4), 1367-1373, 2001; and Physics of Plasmas, 8(5), 2558-2564, 2001, all of which are incorporated herein by reference in their entirety. This system uses a magnetically confined, sheet electron beam to ionize a background gas and produce a planar plasma. Electron beams exhibit high ionization efficiency per watt. The plasma production process is confined to the electron beam volume and is largely independent of both the gas constituents and reactor geometry. Scaling the beam to large dimensions is straightforward, and since the beam dimensions determine the plasma volume, the usable surface area of these plasmas can exceed that of other plasma sources. This combined with the high efficiency allows for the generation of several-square-meter processing areas with readily available laboratory power supplies. At NRL, rectangular plasmas with a thickness of one centimeter and an area of one square meter have been produced.

### SUMMARY

The aforementioned problems of the current technology are overcome by the present invention where in a high-energy electron beam passes through nitrogen gas to form a low electron temperature plasma. The electron beam enhanced nitriding system (EBENS) of the present invention provides a means to modify materials by nitriding using plasmas produced by high-energy electron beams. Electron beam-generated plasmas produce large densities of atomic ions (N⁺) and radicals (N), species shown to be particularly useful in the nitriding process. Indeed, the relative concentrations of these species are considerably larger than those commonly found in existing plasma-based nitriding techniques, and plasmas produced by electron beams have demonstrated advantages over existing approaches for nitriding stainless steel. In addition, electron beam produced plasmas are easily scaled to treat large surface areas (>1 m²) and can be configured to treat difficult geometries such as the interior of pipes or barrels.

Systems based on electron beam generated plasmas have numerous attractive qualities with respect to plasma nitriding. Independent control of the substrate temperature, ion flux, and ion energy is possible since plasma production is independent of the workpiece. In nitrogen atmospheres, these plasmas have comparatively high concentrations of neutral (N) and ionized (N⁺) nitrogen atoms with respect to the molecular (N₂⁺) ions. Both atomic species are commonly thought to promote high nitride layer growth rates at lower workpiece temperatures.

Sheet electron beams are specifically attractive for nitriding planar surfaces of varying dimensions or the exterior surface of a hollow workpiece. Alternatively, in applications where the surface of interest is the interior of a cylinder, such as a pipe, a cylindrical electron beam geometry is optimal. In this configuration, the electron beam could also be collimated by an external magnetic field and the useful characteristics of electron beam-generated plasma will be preserved. In either configuration, electron beam-produced plasmas offer advantages in terms of higher uniformity, efficiency, and potentially unique chemistries compared to conventional sources. This combination of features and the ability to scale to large areas adds a range of control variables that enables EBENS to access operating regimes not possible with conventional nitriding technologies.

The present invention has several advantages over existing technology because of the unique properties of electron beam generated plasmas. In particular, the electron beam improves the efficiency and uniformity in plasma production for varying geometries, while the resulting plasma provides new and alternative chemical pathways for improving nitriding treatments. These features allow for a system that offers greater control over plasma production, expands the ability to control the particle fluxes to the surfaces, increases the effective treatment area, and allows for nitriding unique geometries.

Consider first the ability to regulate the concentrations of plasma species. In conventional sources, gas ionization and dissociation favors the species with the lowest ionization and dissociation energies, and thus these sources provide little control over the relative concentrations of plasma species. High-energy electron beams, on the other hand, create ion and radical species roughly in proportion to the relative gas concentrations, since the electron beam energy is well above the threshold for ionization and dissociation. In practice, the beam current, operating pressure, and gas mixture ratios determine the production rates. The resulting production, and thus concentration of species, is markedly different than other plasma sources and allows control over the production of ion and radical species and ultimately over the flux of these species at the substrate or workpiece. Flux control is further enhanced due to the fact that plasma production is relatively decoupled from reactor geometry so that the substrate can be independently positioned. In EBENS, the ionization region is confined to the beam volume and when the beam is collimated by a magnetic field, the plasma production volume is well defined and localized. The electron beam, for example, can be positioned at a variable distance from a substrate surface. In a nitrogen-rich atmosphere, the relative flux of molecular ions, atomic ions, and radicals then varies strongly with distance, and at large distances, the flux consists mainly of atomic ions (N) and radicals (N). See C. Muratore, S. G. Walton, D. Leonhardt, R. F. Fernsler, D. D. Blackwell, R. A. Meger, “The effect of plasma flux composition on the nitriding rate of stainless steel,” J. Vac. Sci. Technol. A (in press for July/Aug. 2004 issue). This is in contrast to conventional sources where ionization often occurs over the entire chamber volume. Indeed, the relatively high concentrations of N and N⁺ are thought to be responsible for the high rates observed in EBENS when compared to other sources, as illustrated in Table 1.

TABLE 1
A comparison of nitriding results using various approaches. All samples are stainless
steel 316. The nitriding rates from each reference have been normalized to 1 hour using the
following technique: The reported values of layer thickness (d) and corresponding process time
(t) were fit to a parabola with the vertex at the origin (d² = At). The nitriding rate is taken from
the parabola at t = 1 hour. Note that dc diodes are commonly used industrial approaches.

| | Substrate | Maximum | Total | | Ion | Nitriding | |
|---|---|---|---|---|---|---|---|
| | temperature | ion energy | pressure | Gas mixture | current | rate | |
| Process | (° C.) | (eV) | (Pa) | (ratio) | (mA/cm²) | (μm/hr) | Reference |
| rf plasma | 400 | 250 | 0.4 | N₂ | — | 1.2 | 1 |
| dc diode | 350 | 2000 | 5.0 | N₂/H₂ (4:1) | 2.00 | 1.8 | 2 |
| ion beam | 400 | 700 | 0.04 | N₂ | 2.00 | 4.8 | 3 |
| IPAP | 400 | 1000 | 6.7 | N₂/Ar (4:1) | 0.75 | 5.5 | 4 |
| TAT | 420 | 500 | 1.0 | N₂/H₂ (1:3) | “high” | 6.3 | 5 |
| EBENS | 415 | 350 | 21.3 | N₂/Ar (9:1) | 0.55 | 6.8 | 6 |

References (all of which are incorporated herein in their entirety):
1. J. M. Priest, M. J. Baldwin, M. P. Fewell, S. C. Hayden, G. A. Collins, K. T. Short, and J. Tendys, Thin Solid Films, 345 (1999) 113.
2. S. P. Hannula, P. Nenonen, and j. P. Hirvonen, Thin Solid Films, 181 (1989) 343.
3. D. L. Williamson, J. A. Davis, and P. J. Wibur, Surf. Coat. Technol., 103-104 (1998) 178.
4. E. I. Meletis, Surf. Coat. Technol., 149 (2002) 95.
5. A. Leyland, D. B. Lewis, P. R. Stevenson, and A. Matthews, Surf. Coat Technol., 62 (1993) 608.
6. C. Muratore, D. Leonhardt, S. G. Walton, D. D. Blackwell, R. F. Fernsler, and R. A. Meger, Surf. Coat. Technol. (submitted September 2003).

Another advantage of EBENS is the inherently low plasma electron temperature, which is typically below 0.5 eV in nitrogen-based gas mixtures. In other sources, the electron temperature can exceed 2 eV. As a result, the maximum ion energy and thus the spread in ion energy is much lower in EBENS than in systems based on other plasma sources. The principle benefit of such an ion energy distribution is that a narrow initial distribution provides a small variation in the ion energy at biased surfaces. This leads to a selectable, well-defined energy with the nominal energy being determined by the applied bias. A second benefit is that sputtering or ion-induced damage is greatly diminished at grounded surfaces since the incoming ion energies rarely exceed the surface binding energies of most species.

There is no fundamental limit on the physical dimensions of the electron beam, and the efficiency and uniformity of plasma production remain high over the beam volume. The use of electron beam-produced plasmas therefore offers distinct advantages over other plasma sources where scaling to large areas and maintaining uniformity is difficult. Increasing the electron beam dimensions is relatively straightforward, in that the cross-section of the beam is determined by the electron beam source while the length of the beam varies with both beam energy and gas pressure. As noted, plasma sheets with surface areas from 100's to over 10,000 cm² have been produced in a variety of gases with an effective processing area that is nearly identical to the plasma surface area. While sheet plasmas are especially useful for nitriding planar surface areas, cylindrical electron beams have also been produced and the uniform treatment of interior surfaces of cylinders naturally follows from the propagation of the beam along the axis. Scaling electron beams in cylindrical geometries is similar to planar geometries, and thus pipes and tubes of varying dimensions can be treated.

### BRIEF DESCRIPTION OF THE DRAWINGS

These and other objects, features, and advantages of the invention, as well as the invention itself, will become better understood by reference to the following detailed description, appended claims, and accompanying drawings where:

FIG. 1 shows a schematic of an EBENS configuration;

FIG. 2a shows an optical image of nitrided 316 stainless steel using EBENS;

FIG. 2b shows X-ray diffraction measurements comparing a 316 stainless steel sample nitrided using EBENS with an untreated sample; and

FIG. 3 shows a cylindrical EBENS schematic.

### DETAILED DESCRIPTION OF THE PREFERRED EMBODIMENTS

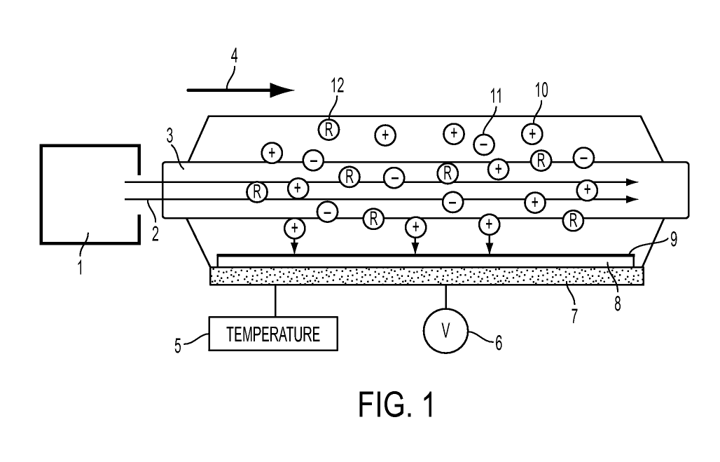

A preferred embodiment of the Electron Beam Enhanced Nitriding System (EBENS) of the present invention as shown in FIG. 1 includes a beam source 1, an electron beam 2, a beam-generated plasma 3, a direction of external magnetic field 4, a temperature control 5, a bias voltage 6, a conducting electrode 7, a substrate 8, a nitride layer 9, a positive ion 10, an electron 11, and a neutral radical 12. EBENS uses a multi-kilovolt (2-5 kV) sheet electron beam that is injected into a nitrogen-based background. The beam is magnetically confined and efficiently ionizes and dissociates the background gas. The beam width (into page) is variable and can exceed a meter. The thickness is up to a few centimeters and is maintained over the beam length by an axial magnetic field that exceeds 100 Gauss. The length of the plasma sheet is determined by the range of the electron beam, which scales roughly as the beam energy squared divided by the gas pressure (E²/P). The range is usually maintained at several times the system length to ensure uniformity in plasma production. The gas pressure typically lies between 10 and 200 mTorr. For the parameters outlined, the beam range is greater than 1 m with electron beam current densities ranging from 1 to 100 mA/cm² over the cross-section of the beam. The plasma densities are as high as ˜10¹² cm⁻³ on axis and are uniform (to within a few percent) over the beam area and most importantly, the processing area. Thus, EBENS is capable of uniformly nitriding surface areas up to and exceeding 1 m².

The plasma electron temperature in electron beam-produced plasmas are low, typically a few tenths of an electron volt (eV) in molecular gases like N₂. The plasma potential is proportional to the electron temperature and is therefore on the order of a few volts in nitrogen-based gases. For grounded surfaces, incident ions will then impact the surface with energies determined by the plasma potential or up to a few eV. Depending on the electron beam current, the flux of ions at a surface can be as high as 10¹⁶ cm⁻²s⁻¹. The result is a large flux of low-energy ions at unbiased surfaces adjacent to the plasma.

The production of ion and radical species depends on the relative gas concentrations and the collision cross-sections for electron impact ionization and dissociation. For an electron beam (e_{b}) injected into pure N₂ background, ions are formed by direct (e_{b}+N₂→N₂⁺+e_{b}+eₚ) and dissociative (e_{b}+N₂→N⁺+N+e_{b}+eₚ) ionization, with the electrons created in the ionization process becoming the plasma electrons (eₚ). N radicals are similarly formed (e_{b}+N₂→2N+e_{b}), albeit in less quantities because of a smaller cross section. For a 2 keV beam, N₂⁺ and N⁺ ions will be created in a ratio of about 4:1. However, N₂⁺ is rapidly destroyed via electron-ion recombination (eₚ+N₂⁺→2N). The recombination rate is a function of electron temperature and increases with decreasing electron energy. The result is an increase in the relative N⁺ density, particularly at locations outside the electron beam. In fact, well outside the beam, the N⁺ density exceeds the N₂⁺ density. In addition to the production of radicals through beam dissociation, the destruction of N₂⁺ through recombination produces two radicals. Thus, given the formation of radicals by ionization, dissociation, and recombination, N and N⁺ ultimately become the dominant plasma species with increasing distance.

In the configuration of FIG. 1, the electron beam-generated plasma is located adjacent to an electrode, upon which the substrate is mounted. Candidate substrate materials include, but are not limited to, ferrous alloys such as stainless steel or aluminum and its alloys. Ions diffuse out of the plasma and impact the substrate with low energies in the absence of any electrode bias. For the best results the substrate is biased and heated. Biasing increases the ion energies to promote the removal of oxides, which hinder the nitriding process. DC biasing is common for conducting materials, while rf biasing is required for insulating materials, such as aluminum nitride. Increasing the workpiece surface temperature enhances nitrogen diffusion into the material. The temperature can be elevated directly and/or indirectly. Note that in some applications it may be feasible to forgo the substrate holder (electrode), provided the substrate can be directly biased and heated. Regardless, the plasma sheet should be somewhat larger than the substrate, so that the ion flux is delivered uniformly over the substrate surface.

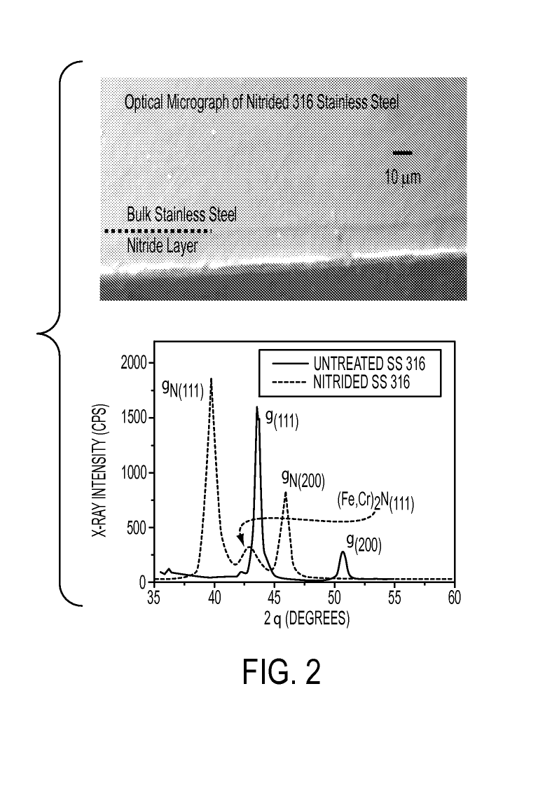

An EBENS prototype has been employed in the nitriding of stainless steel. See C. Muratore, D. Leonhardt, S. G. Walton, D. D. Blackwell, R. F. Fernsler, and R. A. Meter, “Low-temperature nitriding of stainless steel in an electron beam generated plasma,” Surf. Coat. Technol. (2004), in press, the entire contents of which is incorporated herein by reference. For the example shown in FIGS. 2a and 2b, the substrate temperature was approximately 415° C. and the substrate bias was 350 V DC. Through an optical microscope, the nitriding layer is clearly seen to extend from the surface to approximately 12 microns into the bulk. X-ray diffraction measurements of nitrided samples show a shift in the spectrum when compared to untreated samples. This shift is indicative of an expansion of the metal lattice brought about by the incorporation of nitrogen. For these operating conditions the nitriding rate or growth of the nitride layer was found to be 6.8 μm/hr. The rate and layer thickness is dependent on operation conditions such as substrate temperature and bias. For temperatures ranging from 325 to 465° C., the nitride layers were found to vary between 2.2 and 40 microns.

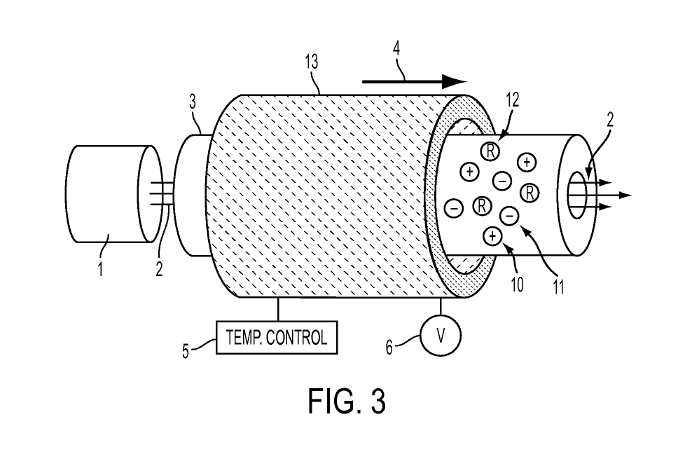

An alternative EBENS configuration shown in FIG. 3 is designed to treat the interior surface of cylinders. The cylindrical EBENS schematic shown in FIG. 3 includes a beam source 1, an electron beam 2, a beam-generated plasma 3, a direction of magnetic field 4, a temperature control 5, a bias voltage 6, a cylindrical workpiece 13, positive ions 10, electrons 11, and neutral radicals 12. In this case, the electron beam is cylindrical and co-axial with the cylinder so as to provide a uniform flux to the surface. The system operating parameters are, in general, similar to the sheet electron beam case. However, here the bias is applied directly to the workpiece, while the temperature is elevated directly or indirectly. Direct means include wrapping the pipe with heating elements, while indirect means include locating heating elements or high power lamps near the workpiece.

In both configurations, a magnetic field is used to collimate the electron beam. However, the fundamental advantages of electron beam-produced plasmas are independent of the magnetic field. That is, the efficiency in plasma production, the low electron temperatures, and the unique plasma chemistries are inherent to electron beam-generated plasmas. The advantage of the magnetic field lies in the ability to provide a uniform electron beam over the region of interest of the effective processing area. Without the magnetic field, the beam will rapidly expand and produce a non-planar, volumetric plasma source. For application where process uniformity is not a critical component, such a system may be useful.

The above description is that of a preferred embodiment of the invention. Various modifications and variations are possible in light of the above teachings. It is therefore to be understood that, within the scope of the appended claims, the invention may be practiced otherwise than as specifically described. Any reference to claim elements in the singular, e.g. using the articles “a,” “an,” “the,” or “said” is not construed as limiting the element to the singular.

1-9. (canceled)

10. A method of nitriding a substrate, comprising the steps of:
a. producing a low electron temperature plasma by passing an electron beam of pre-determined width, length, thickness, and location relative to a surface through a gas comprising nitrogen; and
b. positioning a substrate to be nitrided at a variable distance from the electron beam wherein nitrogen ions diffuse toward and impact the substrate to assist in forming a nitride layer on the substrate.

11. The method of claim 10, wherein said substrate is mounted on an electrode.

12. The method of claim 10, wherein said electron beam has a width much larger in dimension than its thickness.

13. The method of claim 10, wherein magnetic means is used to confine the electron beam to produce a geometrically well-defined, spatially uniform plasma sheet.

14. The method of claim 10, wherein the relative position of said electron beam and substrate is adjustable.

15. The method of claim 10, wherein said substrate is biased, heated, or both.

16. The method of claim 15, wherein said heating may be direct, indirect, or both.

17. The method of claim 10, wherein said substrate comprises a ferrous alloy, aluminum, an aluminum alloy, or any combination thereof.

18. The method of claim 10, wherein said substrate is planar or cylindrical.

19. A nitriding system, comprising:
a. a gas comprising nitrogen;
b. a cylindrical high energy electron beam source;
c. a low electron temperature cylindrical plasma, wherein the plasma is produced by the electron beam passing through the gas; and
d. a cylindrical substrate, the interior of which is to be nitrided, wherein the cylindrical substrate is co-axial with the electron beam and can be positioned at a variable distance from the electron beam;
wherein nitrogen ions and radicals diffuse outward and impact the cylindrical substrate to assist in forming a nitride layer on the interior of the cylindrical substrate.

20. The system of claim 19, additionally comprising magnetic means for confining the electron beam to produce a geometrically well-defined, spatially uniform plasma sheet.

21. The system of claim 19, wherein the relative position of said electron beam and substrate is adjustable.

22. The system of claim 19, wherein said substrate is biased, heated, or both.

23. The system of claim 22, wherein said heating may be direct, indirect, or both.

24. The system of claim 19, wherein said substrate comprises a ferrous alloy, aluminum, an aluminum alloy, or any combination thereof.
